(19) United States
(12) Patent Application Publication
(10) Pub. No.: US 2012/0067416 A1
(43) Pub. Date: Mar. 22, 2012

(54) Photovoltaic Device

(76) Inventor: Seung-Yeop Myong, Seoul (KR)

(21) Appl. No.: 13/308,275

(22) Filed: Nov. 30, 2011

Related U.S. Application Data
(63) Continuation-in-part of application No. 12/762,875, filed on Apr. 19, 2010.

(30) Foreign Application Priority Data
Jun. 12, 2009 (KR) 10-2009-0052234

(51) Int. Cl. H01L 31/02

(52) U.S. Cl. 136/256

(57) ABSTRACT

Disclosed is a photovoltaic device that includes: a substrate; a first electrode disposed on the substrate; a photoelectric transformation layer disposed on the first electrode, the photoelectric transformation layer comprising a light absorbing layer which comprises at least one pair of an intrinsic first sub-layer and an intrinsic second sub-layer, each of which comprises hydrogenated amorphous silicon and hydrogenated proto-crystalline silicon; and a second electrode disposed on the photoelectric transformation layer; wherein a thickness ratio between the first sub-layer and the second sub-layer in each of the pair is constant.

### CROSS-REFERENCE TO RELATED APPLICATIONS

This application is a continuation-in-part application of Ser. No. 12/762,875 filed on Apr. 19, 2010 which claims the benefit of Korean Patent Application No. 10-2009-0052234 filed on Jun. 12, 2009, each of which application is hereby incorporated by reference in its entirety.

### FIELD OF THE INVENTION

This application relates to a photovoltaic device.

### BACKGROUND OF THE INVENTION

Recently, as existing energy sources such as oil and charcoal and so on are expected to be exhausted, attention is now paid to alternative energy sources which can be used in place of the existing energy sources. Among the alternative energy sources, sunlight energy is abundant and has no environmental pollution. For this reason, more and more attention is paid to the sunlight energy.

A photovoltaic device, that is to say, a solar cell converts directly sunlight energy into electrical energy. The photovoltaic device uses mainly photovoltaic effect of semiconductor junction. In other words, when light is incident and absorbed to a semiconductor pin junction formed through a doping process by means of p-type and n-type impurities respectively, light energy generates electrons and holes at the inside of the semiconductor. Then, the electrons and the holes are separated by an internal field so that a photo-electro motive force is generated at both ends of the pin junction. Here, if electrodes are formed at the both ends of junction and connected with wires, an electric current flows externally through the electrodes and the wires.

In order that the existing energy sources such as oil is substituted with the sunlight energy source, it is required that a degradation rate of the photovoltaic device should be low and a stability efficiency of the photovoltaic device should be high, which are produced by the elapse of time.

### SUMMARY OF THE INVENTION

One aspect of this invention includes a photovoltaic device. The photovoltaic device includes: a substrate; a first electrode disposed on the substrate; a photoelectric transformation layer disposed on the first electrode, the photoelectric transformation layer comprising a light absorbing layer which comprises at least one pair of an intrinsic first sub-layer and an intrinsic second sub-layer, each of which comprises hydrogenated amorphous silicon and hydrogenated proto-crystalline silicon; and a second electrode disposed on the photoelectric transformation layer, wherein a thickness ratio between the first sub-layer and the second sub-layer in each of the pair is constant.

The light absorbing layer may be divided into a first area and a second area the first area is constituted by the at least one pair of the first sub-layer and the second sub-layer, and the second area is constituted by a single layer.

### BRIEF DESCRIPTION OF THE DRAWINGS

The embodiment will be described in detail with reference to the following drawings.

FIG. 1 shows a photovoltaic device according to a first embodiment of the present invention.

FIG. 2 shows another photovoltaic device according to a second embodiment of the present invention.

FIGS. 3A to 3H show a manufacturing method of a photovoltaic device according to an embodiment of the present invention.

FIG. 4 shows a plasma-enhanced chemical vapor deposition apparatus for forming a light absorbing layer according to an embodiment of the present invention.

FIG. 5 shows a variation of flow rate of source gas for forming a light absorbing layer according to an embodiment of the present invention.

FIG. 6 shows another variation of flow rate of source gas for forming a light absorbing layer according to an embodiment of the present invention.

FIG. 7 shows further another variation of flow rate of source gas for forming a light absorbing layer according to an embodiment of the present invention.

FIG. 8 shows a light absorbing layer including a plurality of sub-layers included in an embodiment of the present invention.

FIG. 9 shows a light absorbing layer consisting of a hydrogenated proto-crystalline silicon single layer.

### DETAILED DESCRIPTION

Embodiments will be described in a more detailed manner with reference to the drawings.

FIG. 1 shows a photovoltaic device according to a first embodiment of the present invention.

As shown, a photovoltaic device includes a substrate 100, a first electrode 210, a second electrode 250, a photoelectric transformation layer 230 and a protecting layer 300.

In detail, the first electrodes 210 are disposed on the substrate 100. The first electrodes 210 are spaced from each other at a regular interval in such a manner that adjacent first electrodes are not electrically short-circuited. The photoelectric transformation layer 230 is disposed on the first electrode 210 in such a manner as to cover the area spaced between the first electrodes at a regular interval. The second electrodes 250 are disposed on the photoelectric transformation layer 230 and spaced from each other at a regular interval in such a manner that adjacent second electrodes are not electrically short-circuited. In this case, the second electrode 250 penetrates the photoelectric transformation layer 230 and is electrically connected to the first electrode 210 such that the second electrode 250 is connected in series to the first electrode 210. The adjacent photoelectric transformation layers 230 are spaced at the same interval as the interval between the second electrodes. The protecting layer 300 is disposed on the second electrode in such a manner as to cover the area spaced between the second electrodes and the area spaced between the photoelectric transformation layers.

The photoelectric transformation layer 230 includes a p-type semiconductor layer 231, a light absorbing layer 233 and an n-type semiconductor layer 235. The light absorbing layer 233 includes at least one pair of an intrinsic first sub-layer 233A and an intrinsic second sub-layer 233B. The first sub-layer 233A includes a hydrogenated amorphous silicon based material and the second sub-layer 233B includes a hydrogenated proto-crystalline silicon material. Eventhough it is shown in FIG. 1 that the entire light absorbing layer 233 has a structure in which the first sub-layer 233A and second sub-layer 233B are alternately stacked, it is just an example of the present invention. A light abosorbing layer 233 according to an embodiment of the present invention may include a first area of at least one pair of the first sub-layer 233A and second sub-layer 233B and a second area other than the first area. Here, the second area may not have a structure in which the first sub-layer 233A and the second sub-layer 233B are alternately stacked and have a single layer of a hydrogenated amorphous silicon based material. The first area may be disposed to contact with the p-type semiconductor layer 231 and the second area may be disposed to contact with the n-type semiconductor layer 235. It is possible to dispose the first area between the second areas each of which contacting the p-type semiconductor layer 231 and n-type semiconductor layer 235. It is also possible to dispose the first area to contact with the n-type semiconductor layer 235 and to dispose the second area under the first area to contact with the p-type semiconductor layer 231. The degradation rate of a photovoltaic device can be lowered through effectively reducing the recombination loss at a p/i interface by placing the first area closer to the p-type semiconductor layer 231.

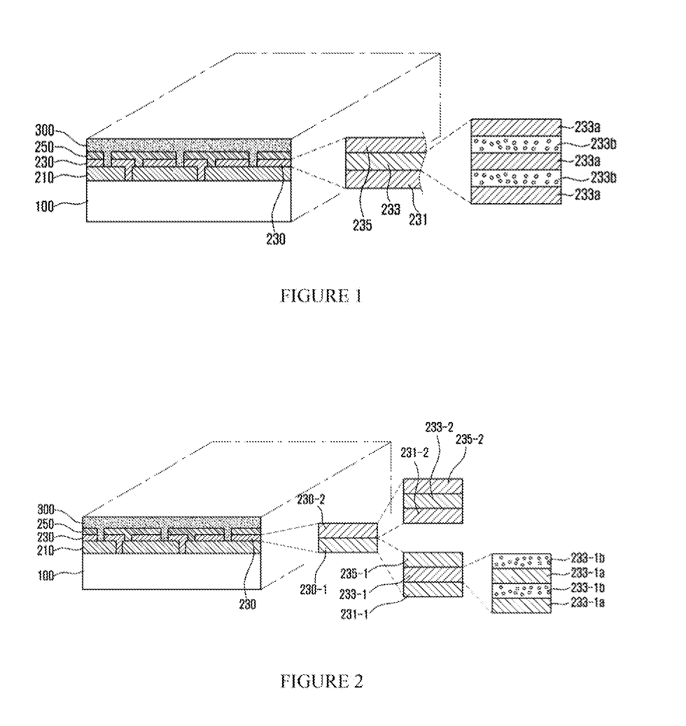

FIG. 2 shows another photovoltaic device according to a second embodiment of the present invention.

Since a photovoltaic device of FIG. 2 is almost similar to that of FIG. 1, descriptions of the same structure will be omitted. In FIG. 2, the photoelectric transformation layer 230 includes a first photoelectric transformation layer 230-1 and a second photoelectric transformation layer 230-2 disposed on the first photoelectric transformation layer. The first photoelectric transformation layer and the second photoelectric transformation layer include a p-type semiconductor layer 231-1 and 231-2, light absorbing layer 233-1 and 233-2 and n-type semiconductor layer 235-1 and 235-2.

The light absorbing layer 233-1 and 233-2 may includes first sub-layer 233-1A and 233-2A and second sub-layer 233-1B and 233-2B stacked on the first sub-layer. Here, the light absorbing layer 233-1 included in the first photoelectric transformation layer 230-1 includes an intrinsic first sub-layer 233-1A and intrinsic second sub-layer 233-113. The first sub-layer 233-1A includes a hydrogenated amorphous silicon based material and the second sub-layer 233-1B includes a hydrogenated proto-crystalline silicon material. The light absorbing layer 233-2 included in the second photoelectric transformation layer 230-2 may include a material which has a lower optical bandgap than the light absorbing layer 233-1 included in the first photoelectric transformation layer 230-1 and can absorb light of relatively longer wavelength, and thus the light usage efficiency can be maximized. The light absorbing layer 233-2 may comprise at least one material of hydrogenated amorphous silicon (a-Si:H), hydrogenated micro-crystalline silicon (μc-Si:H), hydrogenated amorphous silicon germanium (a-SiGe:H), hydrogenated proto-crystalline silicon germanium (pc-SiGe:H) and hydrogenated micro-crystalline silicon germanium (μc-SiGe:H).

While only two photoelectric transformation layers are provided in the present embodiment, three or more photoelectric transformation layers can be also provided. Regarding a second photoelectric transformation layer or a third photoelectric transformation layer among three photoelectric transformation layers, which is far from a side of incident light, the second photoelectric transformation layer or the third photoelectric transformation layer can include a light absorbing layer including a first sub-layer and a second sub-layer. The first sub-layer includes hydrogenated silicon material and the second sub-layer includes hydrogenated proto-crystalline silicon material.

With respect to such photovoltaic devices according to the first and the second embodiments, a manufacturing method of the photovoltaic device will be described below in more detail.

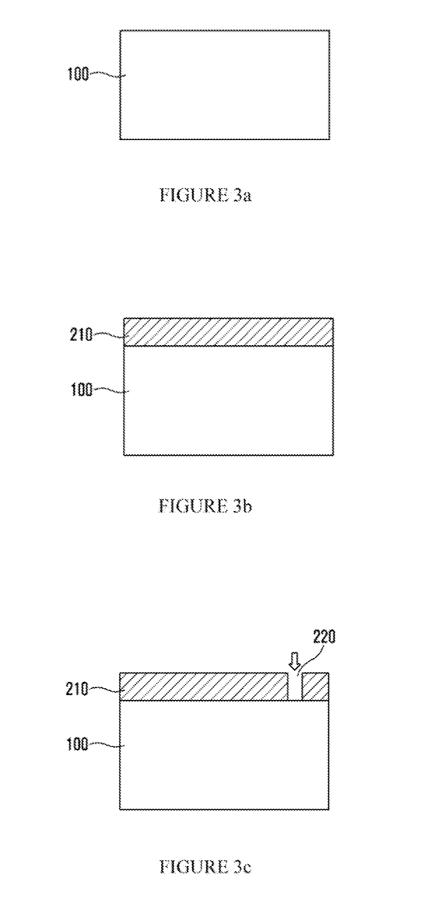

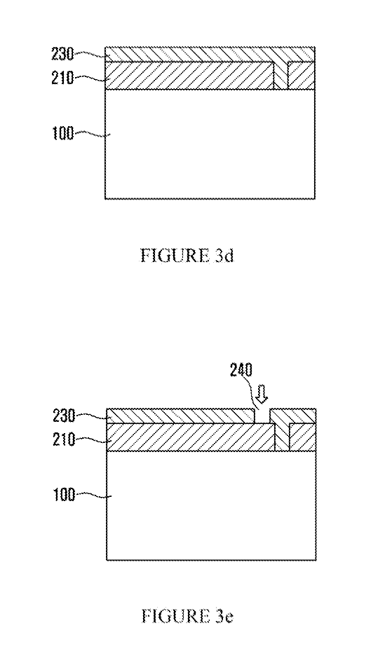

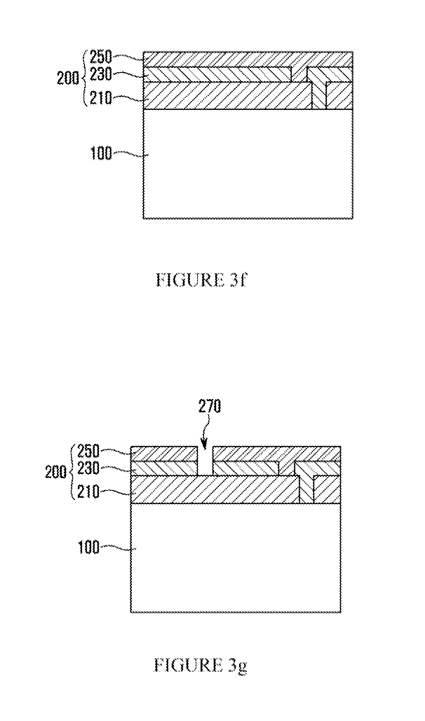

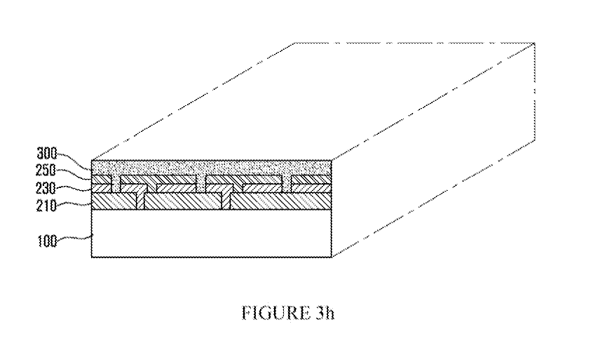

FIGS. 3A to 3H show a manufacturing method of a photovoltaic device according to an embodiment of the present invention.

As shown in FIG. 3A, a substrate 100 is provided first. An insulating transparent substrate 100 can be used as the substrate 100.

As shown in FIG. 3B, a first electrode 210 is formed on the substrate 100. In the embodiment of the present invention, the first electrode 210 can be made by chemical vapor deposition (CVD) or sputtering. The first electrode 210 can be made of transparent conductive oxide (TCO) such as SnO₂ or ZnO.

As shown in FIG. 3C, a laser beam is irradiated onto the first electrode 210 or the substrate 100 so that the first electrode 210 is partially removed. As a result, a first separation groove 220 is formed. That is, since the separation groove 210 penetrates the first electrode 210, preventing adjacent first electrodes from being short-circuited.

As shown in FIG. 3D, at least one photoelectric transformation layer 230 including a light absorbing layer is stacked by CVD in such a manner as to cover the first electrode 210 and the first separation groove 220. In this case, each photoelectric transformation layer 230 includes a p-type semiconductor layer, a light absorbing layer and an n-type semiconductor layer. In order to form the p-type semiconductor layer, source gas including silicon, for example, SiH₄ and source gas including group 3 elements, for example, B₂H₄, am mixed in a reaction chamber, and then the p-type semiconductor layer is formed by PECVD (Plasma Enhanced Chemical Vapor Deposition). Then, the source gas including silicon is flown to the reaction chamber so that the light absorbing layer is formed on the p-type semiconductor layer by PECVD. A method of manufacturing the light absorbing layer will be described later in detail. Finally, reaction gas including group 5 element, for example, PH₃ and source gas including silicon are mixed, and then the n-type semiconductor layer is stacked on an intrinsic semiconductor by PECVD. Accordingly, the p-type semiconductor layer, the light absorbing layer and the n-type semiconductor layer are stacked on the first electrode 210 in order specified.

The light absorbing layer according to the embodiment of the present invention can be included in a single junction photovoltaic device including one photoelectric transformation layer 230 or in a multiple junction photovoltaic device including a plurality of photoelectric transformation layers.

As shown in FIG. 3E, a laser beam is irradiated from the air onto the substrate 100 or the photoelectric transformation layer 230 so that the photoelectric transformation layer 230 is partially removed. A second separation groove 240 is hereby formed in the photoelectric transformation layer 230.

As shown in FIG. 3F, the second electrode 250 is formed by CVD or sputtering process to cover the photoelectric transformation layer 230 and the second separation groove 240. A metal layer made of Al or Ag can be used as the second electrode 250. Also, the second electrode 250 may be made of transparent conductive oxide (TCO) such as ZnO, SnO, or ITO formed by CVD or sputtering.

As shown in FIG. 3G, a laser beam is irradiated from the air onto the substrate 100 so that the photoelectric transformation layer 230 and the second electrode 250 are partially removed. As a result, a third separation groove 270 is formed in the photo voltaic layer 230 and the second electrode 250.

As shown in FIG. 3H, through lamination process, a protecting layer 300 covers partially or entirely a photovoltaic cell 200 including the photoelectric transformation layer 230, the first electrode 210 and the second electrode 250 so as to protect the photovoltaic cell 200. The protecting layer 300 can include encapsulant such as ethylene Vinyl Acetate (EVA) or Poly Vinyl Butiral (PVB).

Through such a process, provided is the photoelectric transformation layer 200 having the protecting layer 300 formed thereon. A backsheet or back glass (not shown) can be made on the protecting layer.

In the next place, a manufacturing method of the light absorbing layer will be described in detail with reference to figures.

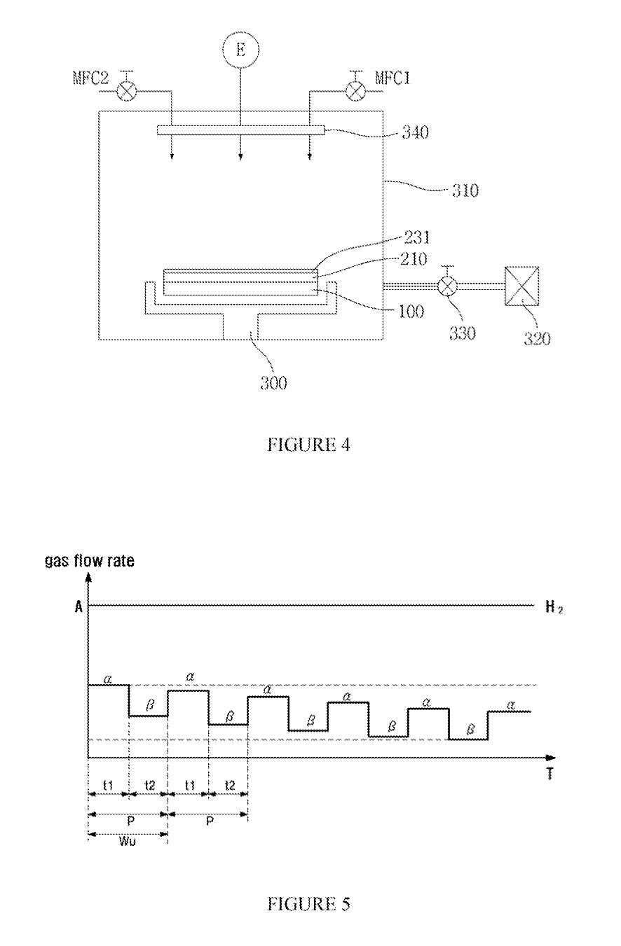

FIG. 4 shows a plasma-enhanced chemical vapor deposition apparatus for forming a light absorbing layer according to an embodiment of the present invention. As shown in FIG. 4, the first electrode 210 and the p-type semiconductor layer 231 are formed on the substrate 100. The substrate 100 is disposed on a plate 300 functioning as an electrode. A vacuum pump 320 operates in order to remove impurities in a chamber 310 before the light absorbing layer forming process. As a result, the impurities in the chamber 310 are removed through an angle valve 330 so that the inside of the chamber 310 is actually in a vacuum state.

When the inside of the chamber 310 is actually in a vacuum state, source gas such as hydrogen (H₂) and silane (SiH₄) is flown to the inside of the chamber 310 through mass flow controllers MFC1 and MFC2 and an electrode 340 having a nozzle formed therein. That is, the hydrogen is flown to the chamber through a first mass flow controller MFC1. The silane is flown to the chamber through a second mass flow controller MFC2. Here, the angle valve 330 is controlled to maintain the pressure of the chamber 310 constant. When the pressure of the chamber 310 is maintained constant, silicon powder caused by turbulence created in the chamber 310 can be prevented from being generated and deposition condition can be maintained constant. The hydrogen is flown to the chamber in order to dilute the silane and reduces Staebler-Wronski effect.

When the source gases are flown to the chamber and a voltage from an electric power source E is supplied to the electrode, an electric potential difference is generated between the electrode 340 and the plate 300. As a result, the source gas is in a plasma state, and the light absorbing layer is deposited on the p-type semiconductor layer 231. In this case, the flow rate of source gas of silane is controlled in accordance with a deposition time such that at least one sub-layer is formed on the p-type semiconductor layer.

FIG. 5 shows a variation of flow rate of source gas for forming a light absorbing layer according to an embodiment of the present invention.

A flow rate A of hydrogen is constant in accordance with the elapse of the deposition time T. A flow rate of the silane varies alternately within a range between a first flow rate value α and a second flow rate value β in accordance with the elapsed deposition time T. The first flow rate value α and the second flow rate value β are reduced in accordance with the elapsed deposition time T. Here, during one cycle P derived from a sum of a duration time of the first flow rate value α and a duration time of the second flow rate value β, the duration time t1 of the first flow rate value α and the duration time t2 of the second flow rate value β are constant in accordance with the elapsed deposition time T.

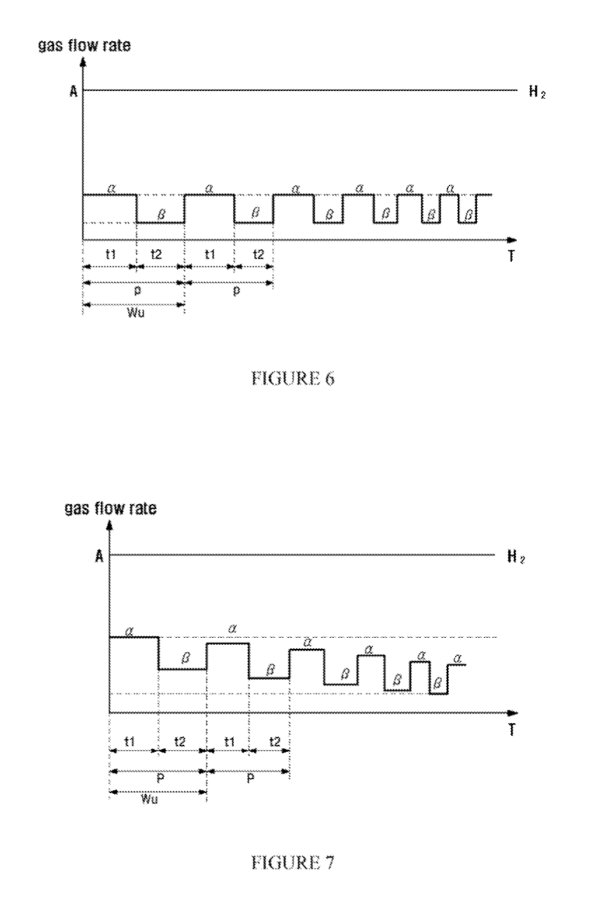

In the embodiment of the present invention, while hydrogen and silane can be supplied according to a graph of FIG. 5, hydrogen and silane can be also supplied according to a graph of FIG. 6.

FIG. 6 shows another variation of flow rate of source gas for forming a light absorbing layer according to an embodiment of the present invention.

As shown in FIG. 6, the flow rate A of hydrogen is constant in accordance with the deposition time T. The flow rate of silane varies alternately within a range between the first flow rate value α and the second flow rate value β in accordance with the elapsed deposition time T. During one cycle P derived from a sum of a duration time of the first flow rate value α and a duration time of the second flow rate value β, the duration time t1 of the first flow rate value α and the duration time t2 of the second flow rate value β are reduced in accordance with the elapsed deposition time T. Here, the first flow rate value α and the second flow rate value β are constant in accordance with the elapsed deposition time T.

In the embodiment of the present invention, hydrogen and silane can be supplied according to a graph of FIG. 5.

FIG. 7 shows further another variation of flow rate of source gas for forming a light absorbing layer according to an embodiment of the present invention.

As shown in FIG. 7, the flow rate A of hydrogen is constant in accordance with the deposition time T. The flow rate of silane varies alternately within a range between the first flow rate value α and the second flow rate value β in accordance with the elapsed deposition time T. During one cycle P derived from a sum of a duration time of the first flow rate value α and a duration time of the second flow rate value β, the duration time t1 of the first flow rate value α and the duration time t2 of the second flow rate value β are reduced in accordance with the elapsed deposition time T. Here, the first flow rate value α and the second flow rate value β are reduced in accordance with the elapsed deposition time T.

As described in FIGS. 5 to 7, in the embodiment of the present invention, the flow rate A of hydrogen is constant in accordance with the deposition time T. A ratio of the duration time t1 of the first flow rate value α to the duration time t2 of the second flow rate value β is also constant. As a result, at least one pair of a first sub-layer 233A and a second sub-layer 233B is formed, and a thickness ratio between the first sub-layer 233A and the second sub-layer 233B in each pair is constant (within an allowable error range). In this case, the flow rate of the silane decreases, varying alternately between the first flow rate value α and the second flow rate value β in accordance with the elapsed deposition time T. This will be described later in detail.

As such, when the flow rate A of hydrogen is constant in accordance with the elapsed deposition time T and the flow rate of silane varies alternately between the first flow rate value α and the second flow rate value β in accordance with the elapsed deposition time T, a hydrogen dilution ratio varies. The hydrogen dilution ratio corresponds to a ratio of the flow rate of hydrogen to the flow rate of silane (that is, A/α, A/β). The first flow rate value α is greater than the second flow rate value β. Therefore, a hydrogen dilution ratio during a time period during which the silane with the first flow rate value α is supplied is less than a hydrogen dilution ratio during a time period during which the silane with the second flow rate value β is supplied.

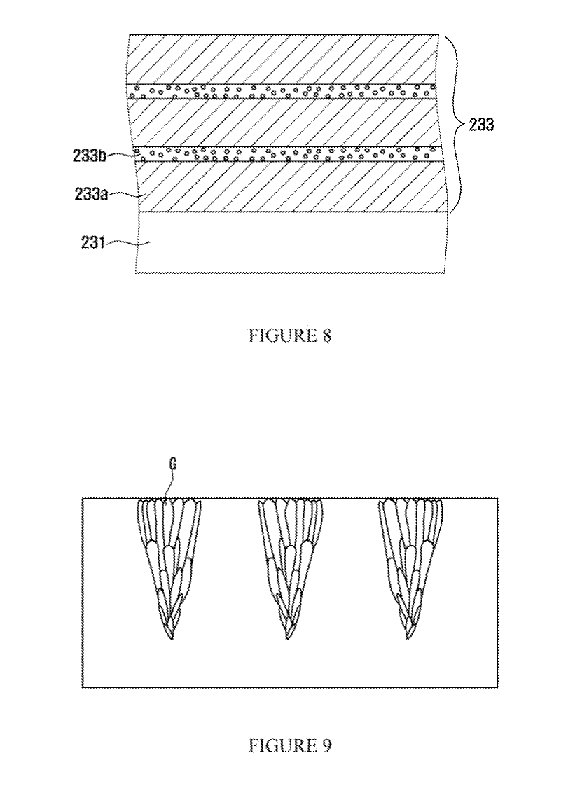

When a hydrogen dilution ratio varies as mentioned above, the light absorbing layer 233 including a plurality of the sub-layers 233A and 233B is formed on the p-type semiconductor layer 231 as shown in FIG. 8. The sub-layers 233A and 233B consist of hydrogenated proto-crystalline silicon sub-layer 233B (pc-Si:H) and hydrogenated amorphous silicon sub-layer 233A (a-Si:H). The hydrogenated proto-crystalline silicon sub-layer 233B (pc-Si:H) includes crystalline silicon grains. The hydrogenated amorphous silicon sub-layer 233A (a-Si:H) includes amorphous silicon. The hydrogenated proto-crystalline silicon sub-layer 233B is produced during the process of a phase change of the amorphous silicon into micro-crystalline silicon. The hydrogenated proto-crystalline silicon has a structure in which crystalline silicon grains (3 to 10 nm in diameter) are embedded in amorphous silicon matrix. Thus, components of crystal silicon are not detected by XRD (X-Ray Diffraction) or Raman Spectroscopy on the hydrogenated proto-crystalline silicon. However, crystalline silicon grains can be detected from HRTEM (High Resolution Transmission Electron Microscopy) images of the hydrogenated proto-crystalline silicon.

Hereinafter, the hydrogenated amorphous silicon sub-layer is referred to as the first sub-layer 233A. The hydrogenated proto-crystalline silicon sub-layer is referred to as the second sub-layer 2338.

In this case, when the hydrogen dilution ratio is low, the first sub-layer 233A of which deposition speed is relatively high is formed. The first sub-layer 233A includes amorphous silicon. When the hydrogen dilution ratio is high, the second sub-layer 233B of which deposition speed is relatively low is formed. The second sub-layer 233B includes a crystalline silicon grain.

Accordingly, the first sub-layer 233A is formed during a time period during which the silane with the first flow rate value α is supplied. The second sub-layer 233B is formed during a time period during which the silane with the second flow rate value β is supplied.

As such, when the light absorbing layer 233 including a plurality of the sub-layers 233A and 233B is made, the degradation rate, i.e., a value which is obtained by dividing a difference between initial efficiency and stabilization efficiency by the initial efficiency, is reduced. Accordingly, the photovoltaic device according to the embodiment of the present invention can have high stabilization efficiency.

in other words, the first sub-layer 233A made of an amorphous silicon based material interrupts columnar growth of the crystalline silicon grain of the second sub-layer 233B. As shown in FIG. 9, when the light absorbing layer is formed of only a proto-crystalline silicon layer unlike the embodiment of the present invention, the columnar growth of the crystalline silicon grain is accomplished. That is to say, as deposition is performed, the diameter of the crystalline silicon grain G is increased.

Such a columnar growth of the crystalline silicon grain increases a recombination rate of carriers such as an electron hole and an electron at a grain boundary, thus the initial efficiency of a photovoltaic device is lowered. Moreover the columnar growth of the crystalline silicon grain lowers the optical bandgap of a light absorbing layer, thus the absorption efficiency for short-wavelength visible light and the short-circuit current are reduced.

However, in the case of the light absorbing layer 233 including a plurality of sub-layers 233A and 233B in the embodiment of the present invention, since a short-range-order (SRO) and a medium-range-Order (MRO) in the silicon thin film matrix are improved, the degradation rate of the light absorbing layer 233 is lowered and the stabilization efficiency is increased. The amorphous silicon of the first sub-layer 233A interrupts columnar growth of the crystalline silicon grain in the second sub-layer 233B and thus the second sub-layer 233B has a uniform thickness, so that a time required for the efficiency of the photovoltaic device to reach the stabilization efficiency is reduced and high stabilization efficiency is obtained.

The crystalline silicon grains of the second sub-layer 233B are covered with amorphous silicon and isolated from each other. The isolated crystalline silicon grains act as radiative recombination centers of some of the captured carriers, and hence suppress photocreation of dangling bonds. As a result, the non-radiative recombination in the amorphous silicon, which surrounds the crystalline silicon grains of the second sub-layer 233B, is reduced.

Meanwhile, since the silane cyclically increases and decreases, the more the deposition time T increases, the more the silane remaining in the chamber 310 can increase. Therefore, the hydrogen dilution ratio is reduced and the thicknesses of the first and the second sub-layers 233A and 233B are not maintained constant. It is also difficult to form the crystalline silicon grain of the second sub-layer 233B. As a result, as the flow rate of the silane varies alternately within a range between the first flow rate value α and the second flow rate value β, the properties of the light absorbing layer 233 can be degraded.

In the embodiment of the present invention, the first flow rate value α and the second flow rate value β of the silane is reduced in accordance with the elapsed deposition time T, offsetting the hydrogen dilution ratio's variation caused by the remaining silane. The properties of the light absorbing layer 233 can be hereby prevented from being degraded.

In the meantime, as described above, the flow rate of hydrogen is constant and the flow rate of silane varies so as to cause the hydrogen dilution ratio to be varied because the flow rate of hydrogen supplied to the inside of the chamber 310 is greater than that of the silane supplied to the inside of the chamber 310, so that it is relatively more difficult to control the flow rate of hydrogen than to control the flow rate of the silane. Therefore, if the flow rate of hydrogen is constant, it is easier to control the hydrogen dilution ratio. In particular, if the flow rate of hydrogen flown to the chamber is constant, turbulence, which is caused by the variation of the flow rate of hydrogen, within the chamber 310 is reduced, improving a film quality of the light absorbing layer 233.

If the flow rate of hydrogen varies within a range between 0 and a certain value so as to cause the hydrogen dilution ratio to be varied, during a period of time during which the flow rate of hydrogen is equal to 0 as the flow rate of hydrogen varies cyclically, that is, a period of time during which hydrogen is not flown from the outside to the chamber, the hydrogen which remains in the chamber 310 increases in accordance with the deposition time T, increasing crystallinity of the sub-layers. As a result, it is difficult to form sub-layers having a uniform crystal size and a uniform thickness.

On the other hand, in the embodiment of the present invention, since the flow rate of hydrogen is constant and the flow rate of the silane is caused to vary cyclically, an amount of hydrogen in the chamber 310 is maintained constant, making it easier to form the sub-layers 233A and 233B having a uniform crystal size and a uniform thickness.

As described above, in the embodiment of the present invention, plasma-enhanced chemical vapor deposition method is used instead of photo-CVD. The photo-CVD is not suitable for manufacturing a large area photovoltaic device. Also, as deposition is performed, a thin film is deposited on a quartz window of a photo-CVD device, reducing UV light penetrating through the quartz window.

For this reason, a deposition rate is gradually reduced and the thicknesses of the first sub-layer 233A and the second sub-layer 233B are gradually reduced. Contrarily, the plasma-enhanced chemical vapor deposition (PECVD) method can solve the shortcomings of the photo-CVD.

As mentioned above, the crystalline silicon grain having a uniform diameter reduces a time required for the efficiency of the photovoltaic device to reach the stabilization efficiency and improves the stabilization efficiency.

To this end, in the embodiment of the present invention, the hydrogen dilution ratio of the chamber 310 is maintained constant while the second sub-layer 233B of the light absorbing layer 233 is repeatedly deposited. In other words, the hydrogen dilution ratio (within an allowable error range) of the second sub-layer 233B is maintained constant in every period that the first and second sub-layers 233A and 233B are formed.

That is, as shown in FIG. 5, the flow rate of hydrogen is constant and a ratio of a time period for supplying the silane with the first flow rate value α to a time period for supplying the silane with the second flow rate value β is constant. The first and the second flow rate values α and β are reduced in accordance with the deposition time in order to offset the remaining silane. Accordingly, the hydrogen dilution ratio within the chamber 310 is maintained constant for the purpose of forming a plurality of the second sub-layers 233B.

As shown in FIG. 6, the flow rate of hydrogen is constant and the first and the second flow rate values α and β of silane are constant. Time periods for supplying the silane with the first and the second flow rate values α and β are reduced in accordance with the deposition time in order to offset the remaining silane. Accordingly, a hydrogen dilution ratio (within an allowable arror range) within the chamber 310 is maintained constant for the purpose of forming a plurality of the second sub-layers 233B.

For this reason above, since the hydrogen dilution ratio within the chamber 310 is maintained constant, a diameter of the crystalline silicon grain of the sub-layer 233B can be maintained constant.

Eventhough it is explained referring to FIG. 5 to FIG. 8 that the entire light absorbing layer 233 has a structure in which the first sub-layer 233A and second sub-layer 233B are alternately stacked, it is just an example of the present invention. A light abosorbing layer 233 according to an embodiment of the present invention may include a first area of at least one pair of the first sub-layer 233A and second sub-layer 233B and a second area other than the first area. Here, the second area may not have a structure in which the first sub-layer 233A and the second sub-layer 233B are alternately stacked and have a single layer of hydrogenated amorphous silicon. The description explained referring to FIG. 5 to FIG. 8 can be applied to form the first area in which the first sub-layer 233A and the second sub-layer 233B are alternately stacked.

By forming the light absorbing layer 233 as mentioned above, not only the high stabilization efficiency of a photovoltaic device but also short time and low cost for manufacturing thereof can be obtained. That is, the time and cost required for manufacturing the light absorbing layer 233 can be reduced by forming the light absorbing layer 233 including the second area of hydrogenated amorphous silicon single layer. Furthermore, the high stabilization efficiency can be obtained due to the lowered degradation rate by forming the light absorbing layer 233 including the first area of the first sub-layer 233A and the second sub-layer 233B alternately stacked.

Hereinafter, a light absorbing layer 233 refers to not only a case that the first sub-layer 233A and second sub-layer 233B are alternately stacked in the entire light absorbing layer 233 but also a case that the first sub-layer 233A and second sub-layer 233B are alternately stacked only in a part of the light absorbing layer 233.

In the embodiment of the present invention, a thickness of the first sub-layer 233A made of amorphous silicon can be equal to or more than 10 nm. A sum of the thickness of the first sub-layer 233A and the thickness of the second sub-layer 233B, which are formed during one cycle P, can be equal to or less than 50 nm. It is more desirable that the sum is less than 30 nm.

Here, during equal to or more than three cycles P, the thickness of the light absorbing layer 233 including the first and the second sub-layers 233A and 23313 can be equal to or more than 150 nm and equal to or less than 350 nm.

For example, if a sum of the thickness of the first sub-layer 233A and the thickness of the second sub-layer 233B, which are formed during one cycle P, is 50 nm, a light absorbing layer 233 can be formed, which has a thickness of 150 nm in three cycles and includes three first sub-layers 233A and three second sub-layers 233B.

When a light absorbing layer 233 having a thickness equal to or more than 150 nm and equal to or less than 350 nm is formed during a time period less than three cycles, the thickness of the first sub-layer 233A made of amorphous silicon layers is excessively increased. If a thickness of the first sub-layer 233A with a relatively low hydrogen dilution ratio becomes large, stabilization efficiency is degraded since recombinations of carriers are increased due to higher photocreation of dangling bonds in the amorphous silicon matrix in accordance with the light incidence thereto.

Here, the thicknesses of the first and second sub-layers 233A and 23313 may not be entirely uniform due to the uncertainty of the process conditions and parameters. An uniformity degree of each thickness of the first and second sub-layers 233A and 233B may be in a range that the deviation from the mean value of the each thickness is equal to or less than 10%. By maintaining the degree of thickness uniformity of each of the first and second sub-layers 233A and 233B in the above mentioned range, it is possible to prevent the properties of the light abosorbing layer 233 from being deteriorated due to the recombination increase in the first sub-layer 233A and the columnar growth of crystal grains in the second sub-layer 233B.

A diameter of a crystalline silicon grain in the second sub-layer 233B can be equal to or more than 3 nm and equal to or less than 10 nm. It is difficult to form a crystalline silicon grain having a diameter less than 3 nm and a degradation rate reduction effect of a solar cell is reduced. If the crystalline silicon grain has a diameter greater than 10 nm, the volume of grain boundary surrounding the crystalline silicon grain is excessively increased. Therefore, carrier recombination also increases and so the efficiency may decrease.

An optical band gap of such a light absorbing layer can be equal to or more than 1.85 eV and equal to or less than 2.0 eV. To form the crystalline silicon grain generates a quantum effect caused by quantum dots. The light absorbing layer 233 according to the embodiment of the present invention has hereby a large optical band gap which is equal to or more than 1.85 eV and equal to or less than 2.0 eV. When a light absorbing layer having an optical band gap equal to or more than 1.85 eV is used in a top cell of a single junction photovoltaic device or a multiple junction photovoltaic device, the light absorbing layer can absorb much light with a short wavelength having a high energy density. If the optical band gap is greater than 2.0 eV, the light absorbing layer 233 including the plurality of sub-layers 233A and 233B is difficult to form and absorption of light is reduced. Therefore, the efficiency can be reduced by reduction of a short-circuit current. The top cell corresponds to a photoelectric transformation layer on which light is first incident among photoelectric transformation layers included in the multiple junction photovoltaic device.

An average hydrogen content of the light absorbing layer 233 including a plurality of the sub-layers 233A and 233B can be equal to or more than 15 atomic % and equal to or less than 25 atomic %. If the average hydrogen content of the light absorbing layer 233 is less than 15 atomic %, the size and density of the quantum dot are reduced, and then the optical band gap of the light absorbing layer 233 can be reduced and the degradation rate of the light absorbing layer 233 can be increased. If the average hydrogen content of the light absorbing layer 233 is greater than 25 atomic %, the diameter of the crystalline silicon grain is excessively increased so that a volume of unstable amorphous silicon is also increased. Accordingly, the degradation rate can be increased.

A warming-up period WU can be provided before starting to deposit the light absorbing layer 233. In other words, as shown in FIGS. 5 to 7, a voltage is not supplied to the electrode 340 of the chamber 310 during a period of time more than a first cycle P for supplying silane with the first flow rate value α and the second flow rate value β. The period of time corresponds to the warming-up period.

Because a voltage is not supplied to the chamber during the warming-up period, plasma is not generated. Since the chamber 310 is in a vacuum state, a condition inside the chamber 310 may not satisfy the deposition condition of the light absorbing layer 233 even though source gas for forming the light absorbing layer 233 is supplied to the chamber.

Therefore, in the case where a deposition is not performed due to no generation of plasma during the warming-up period WU and where a deposition is performed by generation of plasma when a condition inside the chamber 310 satisfies the deposition condition of the light absorbing layer 233 after the warming-up period WU, the light absorbing layer 233 can be stably formed.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures. Moreover, unless the term “means” is explicitly recited in a limitation of the claims, such limitation is not intended to be interpreted under 35 USC 112(6).

What is claimed is:

1. A photovoltaic device comprising:
a substrate;
a first electrode disposed on the substrate;
a photoelectric transformation layer disposed on the first electrode, the photoelectric transformation layer comprising a light absorbing layer which comprises at least one pair of an intrinsic first sub-layer and an intrinsic second sub-layer, each of which comprises hydrogenated amorphous silicon and hydrogenated proto-crystalline silicon; and
a second electrode disposed on the photoelectric transformation layer;
wherein a thickness ratio between the first sub-layer and the second sub-layer in each of the pair is constant.

2. The photovoltaic device of claim 1, wherein the light absorbing layer is divided into a first area and a second area, the first area is constituted by the at least one pair of the first sub-layer and the second sub-layer, and the second area is constituted by a single layer.

3. The photovoltaic device of claim 2, wherein the second area is constituted by the single layer of hydrogenated amorphous silicon.

4. The photovoltaic device of claim 1, wherein a thickness of the light absorbing layer is equal to or more than 150 nm and equal to or less than 350 nm.

5. The photovoltaic device of claim 1, wherein an average hydrogen content of the light absorbing layer is equal to or more than 15 atomic % and equal to or less than 25 atomic %.

6. The photovoltaic device of claim 1, wherein a thickness of the first sub-layer is equal to or more than 10 nm.

7. The photovoltaic device of claim 1, wherein a diameter of a crystalline silicon grain in the hydrogenated proto-crystalline silicon is equal to or more than 3 nm and equal to or less than 10 nm.

8. The photovoltaic device of claim 1, wherein a sum of thicknesses of the first sub-layer and the second sub-layer in each of the pair is equal to or less than 50 nm.

9. The photovoltaic device of claim 1, wherein an optical band gap of the light absorbing layer is equal to or more than 1.85 eV and equal to or less than 2.0 eV.

10. The photovoltaic device of claim 1, wherein the photovoltaic device comprises a plurality of photoelectric transformation layers, and the light absorbing layer is included in the photoelectric transformation layer on which light is first incident among the plurality of photoelectric transformation layers.

11. The photovoltaic device of claim 1, wherein an uniformity degree of each thickness of the first sub-layer and the second sub-layer is in a range that a deviation from the mean value of the each thickness is equal to or less than 10%.

12. The photovoltaic device of claim 2, wherein a thickness of the light absorbing layer is equal to or more than 150 nm and equal to or less than 350 nm.

13. The photovoltaic device of claim 2, wherein an average hydrogen content of the light absorbing layer is equal to or more than 15 atomic % and equal to or less than 25 atomic %.

14. The photovoltaic device of claim 2, wherein a thickness of the first sub-layer is equal to or more than 10 nm.

15. The photovoltaic device of claim 2, wherein a diameter of a crystalline silicon grain in the hydrogenated proto-crystalline silicon is equal to or more than 3 nm and equal to or less than 10 nm.

16. The photovoltaic device of claim 2, wherein a sum of thicknesses of the first sub-layer and the second sub-layer in each of the pair is equal to or less than 50 nm.

17. The photovoltaic device of claim 2, wherein an optical band gap of the light absorbing layer is equal to or more than 1.85 eV and equal to or less than 2.0 eV.

18. The photovoltaic device of claim 2, wherein the photovoltaic device comprises a plurality of photoelectric transformation layers, and the light absorbing layer is included in the photoelectric transformation layer on which light is first incident among the plurality of photoelectric transformation layers.

19. The photovoltaic device of claim 3, wherein the photovoltaic device comprises a plurality of photoelectric transformation layers, and the light absorbing layer is included in the photoelectric transformation layer on which light is first incident among the plurality of photoelectric transformation layers.

20. The photovoltaic device of claim 1, wherein an uniformity degree of each thickness of the first sub-layer and the second sub-layer is in a range that a deviation from the mean value of the each thickness is equal to or less than 10%.
